(19) United States
(12) Patent Application Publication
(10) Pub. No.: US 2024/0310729 A1
(43) Pub. Date: Sep. 19, 2024

(54) METHOD OF PRODUCING MICROSTRUCTURE AND LIQUID EJECTION HEAD

(71) Applicant: CANON KABUSHIKI KAISHA, Tokyo (JP)

(72) Inventors: SATOSHI TSUTSUI, Kanagawa (JP); ISAO IMAMURA, Kanagawa (JP); HIROKI KIHARA, Kanagawa (JP); HARUKA YAMAJI, Tokyo (JP)

(21) Appl. No.: 18/601,794

(22) Filed: Mar. 11, 2024

(30) Foreign Application Priority Data
Mar. 13, 2023 (JP) 2023-038669

(51) Int. Cl. G03F 7/038; B41J 2/14; B41J 2/16; G03F 7/00; G03F 7/039; G03F 7/16

(52) U.S. Cl. CPC G03F 7/038; B41J 2/1433; B41J 2/162; B41J 2/1631; G03F 7/0035; G03F 7/039; G03F 7/161

(57) ABSTRACT

Provided is a method of producing a microstructure including: forming a first resin layer formed of a photosensitive resin composition (1) on a substrate, followed by pattern exposure; and laminating a second resin layer formed of a photosensitive resin composition (2) on the first resin layer having been subjected to the pattern exposure, followed by pattern exposure, wherein the photosensitive resin composition (1) and the photosensitive resin composition (2) each contain an epoxy resin and a photoacid generator, wherein at least one of the photosensitive resin composition (1) or the photosensitive resin composition (2) further contains a coumarone resin, and wherein a content of the coumarone resin is less than 30 parts by mass with respect to 100 parts by mass of a content of each of the epoxy resin of the photosensitive resin composition (1) and the epoxy resin of the photosensitive resin composition (2).

### BACKGROUND

### Field of the Disclosure

The present disclosure relates to a method of producing a microstructure such as a liquid ejection head, and a liquid ejection head.

### Description of the Related Art

A liquid ejection head configured to eject a liquid is given as an example of a microstructure formed by using a photosensitive resin. The liquid ejection head is used in a liquid ejection apparatus such as an ink jet recording apparatus, and includes a flow path forming member and a substrate. The flow path forming member is arranged on the substrate, and defines a flow path of the liquid. The flow path forming member includes a liquid ejection orifice that communicates to the flow path in many cases. Aliquid supply port that communicates to the flow path of the flow path forming member is formed in the substrate. The substrate also includes an energy-generating element that generates ejection energy on a surface side thereof. The liquid is supplied from the liquid supply port to the flow path, is given energy by the energy-generating element, and is ejected from the liquid ejection orifice to impinge on a recording medium such as paper, to thereby enable image formation.

As a method of producing the liquid ejection head, there has been known a method including: laminating, on the substrate having the energy-generating element, a low-sensitivity photosensitive resin layer serving as the flow path of the liquid, and a high-sensitivity photosensitive resin layer and a water-repellent layer each serving as a liquid ejection orifice and a nozzle portion connecting the flow path and the liquid ejection orifice; curing the respective layers; and then removing uncured portions to form a liquid flow path, a nozzle portion, and a liquid ejection orifice. In Japanese Patent Application Laid-Open No. H04-216951, there is a disclosure of a method of producing a liquid ejection head, including: setting a sensitivity ratio to a photosensitive resin layer to be laminated; laminating the photosensitive resin layer serving as a nozzle portion and an ejection orifice without breaking a flow path of an optically determined lower layer; exposing an upper layer; and then collectively developing the lower layer and the upper layer to form a flow path and an ejection orifice.

In addition, in Japanese Patent Application Laid-Open No. 2007-186685, there is a disclosure of a liquid ejection head, which is a cured product using an epoxy resin composition containing an epoxy resin and a photocationic polymerization initiator, so that a flow path wall constituent member of the liquid ejection head has suitable swelling resistance under an environment in which the liquid ejection head is brought into contact with an ink for a long time period.

In a method of producing a liquid ejection head using a cured product having swelling resistance described in Japanese Patent Application Laid-Open No. 2007-186685, for example, when a long time period is required for development as described in Japanese Patent Application Laid-Open No. H04-216951, or when an ink having a high ratio of an organic solvent is used as a liquid to be flowed through a flow path, a crack may occur in the cured product. Such solvent-induced crack of the cured product is sometimes referred to as “solvent crack.” The occurrence of the solvent crack in the vicinity of an ejection orifice of the liquid ejection head may adversely affect printing.

In addition, when the amount of a resin having swelling resistance is reduced in an attempt to suppress the solvent crack, desired swelling resistance may not be obtained.

The problems in the liquid ejection head have been described above. However, the problems are common to microstructures to be brought into contact with similar liquids. For example, a flow path constituent member to be brought into contact with a liquid may be brought into a state of being always exposed to the liquid at the time of the use of a product. In particular, the ink to be typically used for the liquid ejection head is often alkaline, and contains an organic solvent. When the flow path constituent member swells to result in volume swelling owing to its constant contact with such liquid, a microstructure such as a flow path deforms, and hence desired performance may not be obtained, or the flow path constituent member may be peeled from a substrate. Accordingly, the flow path constituent member of the microstructure to be brought into contact with a liquid similarly to the liquid ejection head is strongly required to have swelling resistance. A possible approach to obtaining the swelling resistance is an approach including using a resin excellent in low water absorptivity or a resin providing a high crosslinking density, or increasing the crosslinking density of the member through, for example, a change in process condition, such as an increase in exposure value or heat treatment temperature. However, when the usage amount of the resin excellent in low water absorptivity or the resin providing a high crosslinking density, or the crosslinking density of the member is simply increased, the solvent crack or the like may occur at the time of the production, and hence it may be difficult to keep a pattern shape having satisfactory accuracy in the microstructure.

### SUMMARY

In view of the foregoing, an object of the present disclosure is to provide a method of producing a microstructure in which both of swelling resistance and shape stability are achieved, in a liquid ejection head.

According to one embodiment of the present disclosure, there is provided a method of producing a microstructure including: forming a first resin layer formed of a photosensitive resin composition (1) on a substrate, followed by pattern exposure; and laminating a second resin layer formed of a photosensitive resin composition (2) on the first resin layer having been subjected to the pattern exposure, followed by pattern exposure, wherein the photosensitive resin composition (1) and the photosensitive resin composition (2) each contain an epoxy resin and a photoacid generator, wherein at least one of the photosensitive resin composition (1) or the photosensitive resin composition (2) further contains a coumarone resin, and wherein a content of the coumarone resin is less than 30 parts by mass with respect to 100 parts by mass of a content of each of the epoxy resin of the photosensitive resin composition (1) and the epoxy resin of the photosensitive resin composition (2).

According to one embodiment of the present disclosure, there is provided a liquid ejection head including: a substrate; and a flow path forming member and an ejection orifice forming member arranged on the substrate, wherein the flow path forming member and the ejection orifice forming member are formed of cured products of a photosensitive resin composition (1) and a photosensitive resin composition (2) each containing an epoxy resin and a photoacid generator, respectively, wherein at least one of the photosensitive resin composition (1) or the photosensitive resin composition (2) further contains a coumarone resin, and wherein a content of the coumarone resin is less than 30 parts by mass with respect to 100 parts by mass of a content of each of the epoxy resin of the photosensitive resin composition (1) and the epoxy resin of the photosensitive resin composition (2).

Further features of the present disclosure will become apparent from the following description of exemplary embodiments with reference to the attached drawings.

### BRIEF DESCRIPTION OF THE DRAWINGS

FIG. 1A is a schematic perspective view for illustrating the configuration of a liquid ejection head according to one embodiment of the present disclosure.

FIG. 1B is a schematic sectional view taken along the line A-A′ of FIG. 1A.

FIG. 2A is a schematic view of a film base material, according to one embodiment of the present disclosure.

FIG. 2B is a schematic view for illustrating a transfer material, according to one embodiment of the present disclosure.

FIG. 3A is a schematic sectional view of a substrate, according to one embodiment of the present disclosure.

FIG. 3B is a schematic sectional view for illustrating the substrate having formed thereon an inorganic material layer, according to one embodiment of the present disclosure.

FIG. 3C is a schematic sectional view of the substrate having formed therein a supply port, according to one embodiment of the present disclosure.

FIG. 3D is a schematic sectional view of the substrate having transferred thereonto a first resin layer, according to one embodiment of the present disclosure.

FIG. 3E is a schematic sectional view for illustrating a step of exposing the first resin layer, according to one embodiment of the present disclosure.

FIG. 3F is a schematic sectional view of the substrate having transferred thereonto a second resin layer, according to one embodiment of the present disclosure.

FIG. 3G is a schematic sectional view for illustrating a step of exposing the second resin layer, according to one embodiment of the present disclosure.

FIG. 3H is a schematic sectional view of a liquid ejection head, according to one embodiment of the present disclosure.

### DESCRIPTION OF THE EMBODIMENTS

Exemplary embodiments of the present disclosure are described below with reference to the drawings. In the following description, a case in which a method of producing a microstructure based on the present disclosure is applied to the production of a liquid ejection head is described as an example. However, the method of producing a microstructure of the present disclosure is not limited to the application to the production of a liquid ejection head. In addition, in the following description, the same number is given to configurations having the same function in the drawings, and their description may be omitted. In the present disclosure, the description “XX to YY” representing a numerical range means a numerical range including a lower limit and an upper limit that are end points unless otherwise stated. When the numerical ranges are described in stages, the upper and lower limits of each numerical range may be arbitrarily combined.

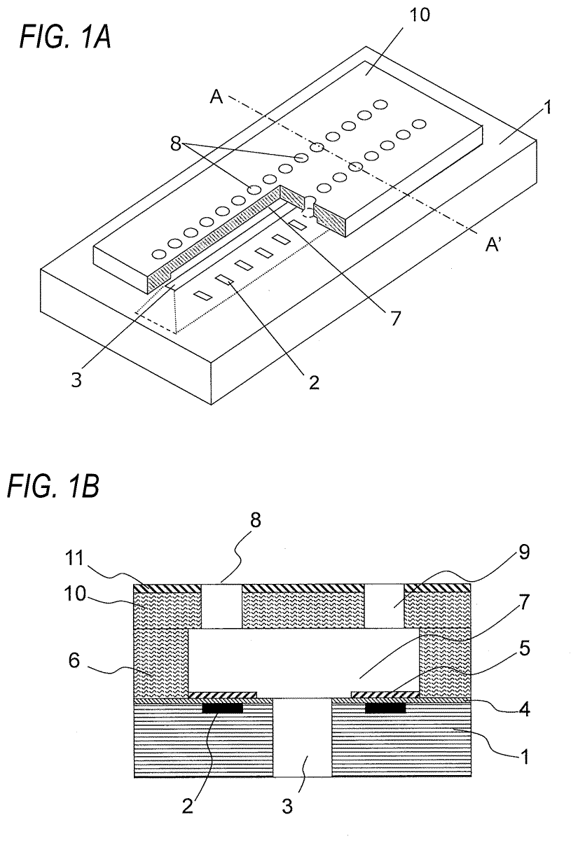

FIG. 1A is a schematic perspective view for illustrating a liquid ejection head according to one embodiment of the present disclosure. In addition, FIG. 1B is a schematic sectional view of the liquid ejection head according to one embodiment of the present disclosure viewed from a plane perpendicular to its substrate, the plane passing the line A-A′ in FIG. 1A.

The liquid ejection head illustrated in each of FIG. 1A and FIG. 1B includes a substrate 1 in which energy-generating elements 2 configured to generate energy for ejecting a liquid are formed at predetermined pitches. The substrate 1 is, for example, a silicon substrate formed of silicon. The silicon substrate is preferably a silicon single crystal whose surface has a crystal orientation of (100). Examples of the energy-generating elements 2 include an electrothermal conversion element and a piezoelectric element. For example, tantalum silicon nitride (TaSiN) serving as a resistance heating element may be used as the electrothermal conversion element. The energy-generating elements 2 may be arranged so as to be in contact with the surface of the substrate 1, or may be arranged so as to be partially hollow with respect to the surface of the substrate 1. Control signal input electrodes (not shown) for operating the energy-generating elements 2 are connected to the energy-generating elements 2. In addition, the substrate 1 has opened therein a liquid supply port (hereinafter also referred to as “supply port”) 3 configured to supply a liquid (ink).

An inorganic material layer 4 and a protective layer 5 are formed on the surface side of the substrate 1. Examples of the inorganic material layer 4 include silicon oxide (SiO₂), silicon nitride (SiN), silicon carbide (SiC), silicon carbonitride (SiCN), and silicon oxycarbide (SiOC). In each of FIG. 1A and FIG. 1B, the inorganic material layer 4 is used as a heat storage layer or an insulating layer. The protective layer 5 protects the energy-generating elements, and is formed of, for example, tantalum (Ta) or iridium (Ir). The inorganic material layer 4 may cover the energy-generating elements 2.

In each of FIG. 1A and FIG. 1B, the inorganic material layer 4 is formed on substantially the entire surface of the substrate 1. The side walls of a flow path 7 are formed by a flow path forming member 6 on the inorganic material layer 4. Further, an ejection orifice forming member 10 having ejection orifices 8 and nozzle portions 9 is formed on the flow path forming member 6 and the flow path 7. In addition, a liquid repellent layer 11 is formed on the ejection orifice forming member 10 as required.

The liquid ejection head is configured to eject the ink supplied from the supply port 3 through the flow path 7 as liquid droplets (ink droplets) from the ejection orifices 8 through the nozzle portions 9 by applying a pressure generated by the energy-generating elements 2 to the ink.

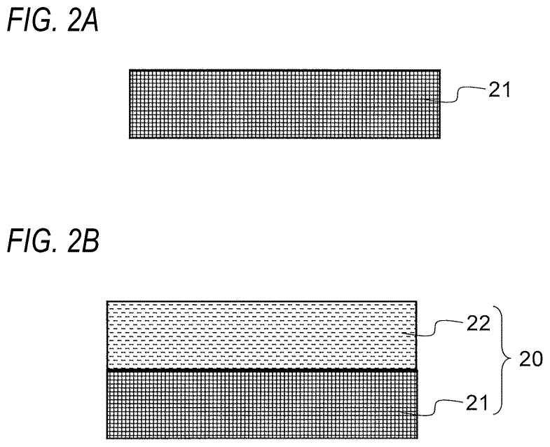

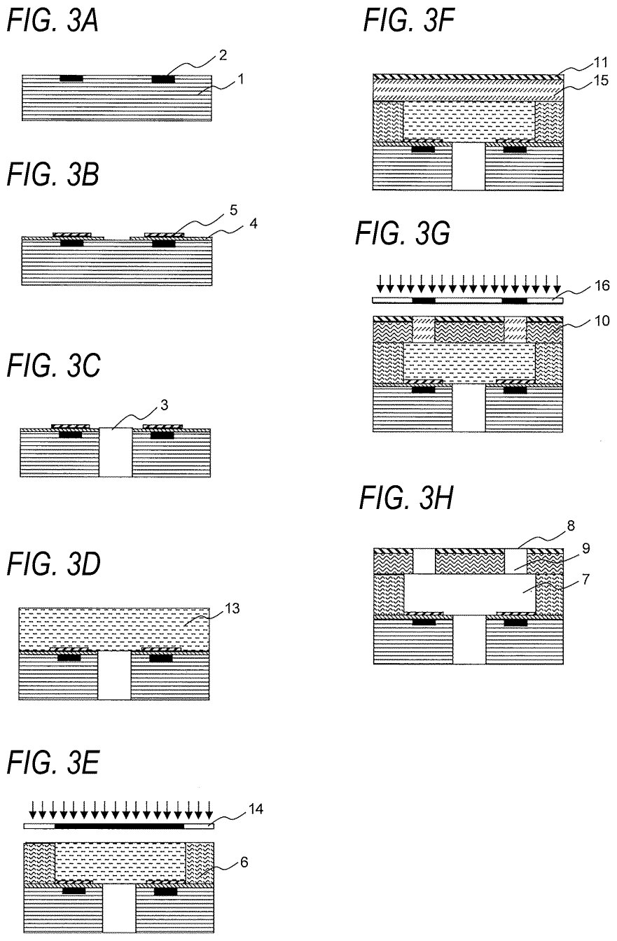

Next, a method of producing the liquid ejection head according to this embodiment is described below with reference to FIG. 2A to FIG. 3H.

FIG. 2A and FIG. 2B are each a schematic sectional view for illustrating an example of a method of producing a transfer material (dry film) having a resin layer formed of a photosensitive resin composition.

FIG. 3A to FIG. 3H are each a schematic sectional view for illustrating an example of the method of producing the liquid ejection head according to this embodiment, and are each a view when the head is viewed under a completed state at the same cross section as that of FIG. 1B.

First, as illustrated in FIG. 2A, a film base material 21 formed of, for example, polyethylene terephthalate (PET) or polyimide is prepared. Next, as illustrated in FIG. 2B, a photosensitive resin composition is applied to the film base material 21 by, for example, a spin coating method or a slit coating method, and is prebaked to form a resin layer 22 formed of the photosensitive resin composition. Thus, a transfer material 20 is produced.

The photosensitive resin composition contains an epoxy resin and a photoacid generator. Further, at least one of a photosensitive resin composition (1) or a photosensitive resin composition (2) to be described later contains a coumarone resin. In addition, the content of the coumarone resin is less than 30 parts by mass with respect to 100 parts by mass of the content of the epoxy resin in each resin layer. In this case, a resin layer formed of the photosensitive resin composition (1) is called a first resin layer, and a resin layer formed of the photosensitive resin composition (2) is called a second resin layer.

The photosensitive resin composition (1) is preferably a negative cationically polymerizable resin composition containing at least an epoxy resin having a weight-average molecular weight (Mw) of 5,000 or more, a softening point of 140° C. or more, and an epoxy equivalent of 2,300 or less, a photoacid generator, and a solvent. Further, when the first resin layer is arranged so as to be in contact with the inorganic material layer, the photosensitive resin composition (1) preferably contains, as an additive, a polyhydric alcohol that has 2 or 3 hydroxy groups at its terminal and is free of a perfluoroalkyl group or a perfluoroalkylene group. Details about the composition are described later.

A production process for the liquid ejection head using such transfer material is described with reference to FIG. 3A to FIG. 3H.

As illustrated in FIG. 3A, the substrate 1 having the energy-generating elements 2 on its surface side is prepared.

As illustrated in FIG. 3B, the inorganic material layer 4 is formed on the surface side of the substrate 1 so as to cover the energy-generating elements 2. In addition, the protective layer 5 is formed above the energy-generating elements 2 so as to be in contact with the inorganic material layer 4. The inorganic material layer 4 and the protective layer 5 are subjected to patterning as required.

As illustrated in FIG. 3C, the supply port 3 that penetrates the substrate and is configured to supply the ink is formed. The supply port 3 is formed at a desired position by using wet etching with an alkaline etching liquid such as tetramethylammonium hydroxide (TMAH), or dry etching such as reactive ion etching.

As illustrated in FIG. 3D, a first resin layer 13 formed of the photosensitive resin composition (1) is transferred onto the inorganic material layer 4 of the substrate 1 having arranged therein the energy-generating elements 2 and the supply port 3 by using a lamination method to be formed thereon. A method for the formation may be a method including transferring the layer to the substrate while heating the layer. In the case of a substrate in which the supply port 3 is not arranged, the film formation may be performed through the application of the photosensitive resin composition (1) by, for example, a spin coating method or a slit coating method without turning the composition into the transfer material. The first resin layer 13 formed of the photosensitive resin composition (1) is preferably formed of a cationically polymerizable resin composition in consideration of, for example, its adhesiveness to the ejection orifice forming member 10 to be described later, mechanical strength, stability against a liquid such as ink, and resolution.

The thickness of the first resin layer 13 formed of the photosensitive resin composition (1) corresponds to the height of the flow path, and is hence appropriately determined by the ejection design of the liquid ejection head; the thickness is preferably set to, for example, from 3 μm to 45 μm.

As illustrated in FIG. 3E, the first resin layer 13 is subjected to pattern exposure through a flow path forming mask 14 having a flow path pattern. Further, heat treatment (post exposure baking: PEB) is performed to cure the exposed portion of the layer. Thus, the flow path forming member 6 formed of a cured product of the photosensitive resin composition (1) is formed. The flow path forming mask 14 is obtained by forming a light-shielding film such as a chromium film on a substrate formed of a material that transmits light having an exposure wavelength, such as glass or quartz, in accordance with the pattern of the flow path or the like. A projection exposure apparatus having a light source having a single wavelength, such as an i-line exposure stepper or a KrF stepper, or a projection exposure apparatus having a broad-wavelength mercury lamp as a light source, such as MASK ALIGNER MPA-600 Super (product name, manufactured by Canon Inc.), may be used as an exposure apparatus.

As illustrated in FIG. 3F, a second resin layer 15 formed of the photosensitive resin composition (2) is transferred onto the first resin layer 13 that is unexposed and the flow path forming member 6 by using a lamination method to be formed thereon. The second resin layer 15 formed of the photosensitive resin composition (2) is used for producing a transfer material by the method illustrated in FIG. 2A and FIG. 2B in the same manner as in the first resin layer 13. Further, the liquid repellent layer 11 is formed on the second resin layer 15. The photosensitive resin composition (2) serving as the ejection orifice forming member 10 preferably has sensitivity higher than that of the photosensitive resin composition (1). The photosensitive resin composition (2) contains an epoxy resin and a photoacid generator, and is particularly preferably a negative cationically polymerizable resin composition containing a polyfunctional epoxy resin that is trifunctional or more and has a benzene ring, and a photoacid generator. Details about the composition are described later. The photosensitive resin composition (2) is preferably formed of a cationically polymerizable epoxy resin composition in consideration of, for example, its adhesiveness to the flow path forming member 6, mechanical strength, stability against a liquid such as ink, and resolution.

In addition, the thickness of the second resin layer 15 is appropriately determined by the ejection design of the liquid ejection head, and is hence not particularly limited. However, the thickness is preferably set to, for example, from 3 μm to 25 μm from the viewpoint of the mechanical strength or the like.

The liquid repellent layer 11 is required to have liquid repellency against a liquid such as ink, and a fluorine compound having cationic polymerizability, such as a perfluoroalkyl composition or a perfluoropolyether composition, is preferably used as a liquid repellent. Further, an epoxy resin is preferably added to the fluorine compound from the viewpoint of a patterning property. In addition, a liquid repellent prepared by dissolving the fluorine compound in an organic solvent such as an alcohol is preferably used from the viewpoint of applicability. It has been generally known that the fluoroalkyl chain of the perfluoroalkyl composition or the perfluoropolyether composition is unevenly distributed to an interface between the composition and air by baking treatment after its application. Accordingly, the liquid repellency of the surface of the liquid repellent layer can be improved.

As illustrated in FIG. 3G, the second resin layer 15 formed of the photosensitive resin composition (2) and the liquid repellent layer 11 are subjected to pattern exposure through an ejection orifice forming mask 16 having an ejection orifice pattern. Further, heat treatment (PEB) is performed to cure the exposed portions of the layers. Thus, the ejection orifice forming member 10 is formed as a cured product. When the second resin layer 15 is exposed to light having the same wavelength as that of the light to be used in the exposure of the first resin layer 13, an exposure value for curing the second resin layer 15 is preferably made smaller than an exposure value for curing the first resin layer 13. In other words, when the quantity of the light that has passed the second resin layer 15 at the time of the exposure of the second resin layer 15 is the exposure value for curing the unexposed portion of the first resin layer 13, it becomes difficult to remove the first resin layer 13 that is unexposed in a developing step, and hence the flow path 7 cannot be formed with satisfactory accuracy. In view of the foregoing, when the exposure is performed with exposure light including light having the same wavelength, the photosensitive resin composition (2) preferably has sensitivity relatively higher than that of the photosensitive resin composition (1). The ejection orifice forming mask 16 is obtained by forming a light-shielding film such as a chromium film on a substrate formed of a material that transmits light having an exposure wavelength, such as glass or quartz, in accordance with the ejection orifice pattern. A projection exposure apparatus having a light source having a single wavelength, such as an i-line exposure stepper or a KrF stepper, or a projection exposure apparatus having a broad-wavelength mercury lamp as a light source, such as MASK ALIGNER MPA-600 Super (product name, manufactured by Canon Inc.), may be used as an exposure apparatus.

As illustrated in FIG. 3H, the unexposed portions (uncured portions) of the first resin layer 13, the second resin layer 15, and the liquid repellent layer 11 are developed with a developing liquid to be collectively removed. Thus, the flow path 7, the ejection orifices 8, and the nozzle portions 9 are formed. Heat treatment (PEB) is performed as required to complete the liquid ejection head. Examples of the developing liquid include propylene glycol monomethyl ether acetate (PGMEA), methyl isobutyl ketone (MIBK), and xylene. In addition, rinsing treatment with isopropyl alcohol (IPA) or the like may be performed as required.

With regard to the method of producing the liquid ejection head of the present disclosure, in the above-mentioned production method, the second resin layer 15 is laminated on the flow path forming member 6 and the unexposed portion of the first resin layer 13 after the step of subjecting the first resin layer 13 to pattern exposure to form the flow path forming member 6. However, the second resin layer 15 may also be laminated before the exposure of the first resin layer 13.

In addition, in the above-mentioned method of producing the liquid ejection head of the present disclosure, the flow path forming member 6 and the ejection orifice forming member 10 are formed in two layers. However, the present disclosure is not limited to the mode. The respective members may be formed by using a plurality of photosensitive resins.

The photosensitive resin compositions in the present disclosure are described below.

The photosensitive resin composition (1) and the photosensitive resin composition (2) for forming the flow path forming member and the ejection orifice forming member in the present disclosure each contain the epoxy resin and the photoacid generator. In particular, the compositions are each preferably a negative cationically polymerizable resin composition in consideration of, for example, the adhesive performance, mechanical strength, liquid (ink) resistance, swelling resistance, reactivity as a photolithography material, and resolution of a cured product thereof. More specifically, the compositions are each preferably a photocationically polymerizable epoxy resin composition containing, for example, a bisphenol A-type or F-type epoxy resin, a phenol novolac-type epoxy resin, a cresol novolac-type epoxy resin, or a polyfunctional epoxy resin having a norbornene skeleton, a terpene skeleton, a dicyclopentadiene skeleton, an oxycyclohexane skeleton, or the like. In addition, an epoxy resin having 2 or more epoxy groups (epoxy resin that is bifunctional or more) is preferably used in each of the photosensitive resin composition (1) and the photosensitive resin composition (2). Such use is suitable for obtaining desired characteristics because a cured product of each of the photosensitive resin compositions is three-dimensionally crosslinked.

The photosensitive resin composition contains a coumarone resin in at least one of the photosensitive resin composition (1) or the photosensitive resin composition (2) in addition to the epoxy resin. A coumarone resin having a weight-average molecular weight (Mw) of from 500 to 1,000 is preferably used as the coumarone resin from the viewpoints of the patterning property and the swelling resistance. In addition, the coumarone resin preferably has a hydroxyl value of 40 or less from the viewpoints of reactivity with the epoxy resin and the swelling resistance. When the above-mentioned molecular weight and hydroxyl value are satisfied, the compatibility with the epoxy resin also becomes satisfactory. In addition, the coumarone resin preferably has a softening point of 90° C. or more from the viewpoint of the shape stability of the cured product. In addition, when a liquid repellent layer is to be applied and formed on the photosensitive resin layer with a liquid repellent containing a solvent such as an alcohol, the coumarone resin is preferably insoluble in an alcohol solvent for preventing the photosensitive resin layer from dissolving at the time of the application of the liquid repellent layer.

The coumarone resin needs to be less than 30 parts by mass with respect to 100 parts by mass of the content of the epoxy resin in the photosensitive resin composition (1) from the viewpoints of a patterning property, transferability at the time of formation as a dry film, and compatibility with another layer at the time of lamination. Further, the content is preferably 25 parts by mass or less, more preferably 15 parts by mass or less. The lower limit value is 0 parts by mass when the composition is free of the coumarone resin, but when the composition contains the coumarone resin, the content is preferably 1 part by mass or more, more preferably 2.5 parts by mass or more with respect to 100 parts by mass of the epoxy resin.

In addition, the coumarone resin is less than 30 parts by mass with respect to 100 parts by mass of the content of the epoxy resin in the photosensitive resin composition (2) from similar viewpoints. The content is preferably 25 parts by mass or less, more preferably 15 parts by mass or less. The lower limit value is 0 parts by mass when the composition is free of the coumarone resin, but when the composition contains the coumarone resin, the content is preferably 1 part by mass or more, more preferably 2.5 parts by mass or more with respect to 100 parts by mass of the epoxy resin.

In the case of the liquid ejection head obtained by thermally transferring and laminating the photosensitive resin layer onto the substrate having an opening or a depressed portion, the first resin layer 13 for forming the flow path forming member preferably has heat resistance against the thermal step of the second resin layer 15 rather than the pattern shape stability of the nozzle portions of the ejection orifice forming member. For example, diffusion of both the compositions between the photosensitive resin layers having been laminated is preferably prevented from occurring through a thermal step, such as the heating at the time of the transfer or the heat treatment after exposure (PEB) of the photosensitive resin composition (2) having higher sensitivity than that of the photosensitive resin composition (1) to be laminated. Accordingly, it is preferred that the epoxy resin in the photosensitive resin composition (1) be bifunctional or more and have a high weight-average molecular weight. Specifically, an epoxy resin having a weight-average molecular weight (Mw) of from 5,000 to 600,000 and a softening point of 140° C. or more is preferred. When the Mw is 5,000 or more, in the thermal step, the unexposed portion of the first resin layer 13 formed of the photosensitive resin composition (1) can be suppressed from largely falling to the supply port 3 serving as an opening portion of the substrate. When the first resin layer 13 that is unexposed largely falls from the opening, the height of each resin layer becomes nonuniform. Meanwhile, when the Mw is 600,000 or less, a situation in which the crosslinking density of the photosensitive resin composition reduces to reduce the pattern shape stability can be suppressed. In addition, when the softening point of the epoxy resin is 140° C. or more, diffusion of components in both the compositions between the photosensitive resin layers having been laminated can be suppressed through the thermal step, such as the heating at the time of the transfer or the PEB of the photosensitive resin composition (2) having higher sensitivity than that of the photosensitive resin composition (1) to be laminated.

Further, it is preferred that a dispersion degree (Mw/Mn), which is a ratio of the weight-average molecular weight (Mw) to a number-average molecular weight (Mn), be less than 3, and the epoxy equivalent be 2,300 or less from the viewpoint of resolution. When the Mw/Mn is 3 or more or when the epoxy equivalent is more than 2,300, the reactivity of the epoxy resin may reduce. The reduction in reactivity may induce occurrence of unevenness on a pattern side wall of the cured product of the photosensitive resin composition (1) because the curing of the epoxy resin is insufficient and the epoxy resin of the exposed portion elutes in the development.

In addition, the photosensitive resin composition (1) preferably contains an epoxy resin that is trifunctional or more and has a Mw of more than 5,000 in addition to the epoxy resin that is bifunctional or more from the viewpoint of the reactivity. The incorporation of the epoxy resin that is trifunctional or more allows the crosslinking of the photosensitive resin composition to three-dimensionally advance, and hence can improve the sensitivity thereof as a photosensitive material. The epoxy resin that is trifunctional or more preferably has an epoxy equivalent of less than 500. When the epoxy equivalent is less than 500, the sensitivity is sufficiently obtained, and hence a reduction in pattern resolution, or a reduction in mechanical strength or adhesiveness of a cured product of the composition can be suppressed. When the bifunctional epoxy resin and the epoxy resin that is trifunctional or more are used, a mixing ratio “bifunctional epoxy resin/epoxy resin that is trifunctional or more” is preferably from 0.3 to 5.0 (mass ratio) from the viewpoints of the heat resistance and the adhesiveness. When the ratio “bifunctional epoxy resin/epoxy resin that is trifunctional or more” is 0.3 or more, the heat resistance is sufficiently obtained. With regard to the softening point when the photosensitive resin composition (1) is formed into a dry film, a composition having the above-mentioned mass ratio using an epoxy resin having a softening point of 140° C. or more is preferred. With this, the dry film of the photosensitive resin composition (1) has a softening point higher than that of the photosensitive resin composition (2) by 10° C. or more, and diffusion of both the compositions between the photosensitive resin layers having been laminated can be suppressed. In addition, when the ratio “bifunctional epoxy resin/epoxy resin that is trifunctional or more” is 5.0 or less, swelling at the time of the contact thereof with a liquid such as ink is suppressed, and hence the reduction in adhesiveness can be suppressed.

In addition, the photosensitive resin composition (1) preferably contains a polyhydric alcohol having hydroxy groups at its terminals from the viewpoint of its adhesiveness to the inorganic material layer 4 and from the viewpoint of reactivity between the epoxy resin and the coumarone resin. The addition of the polyhydric alcohol having hydroxy groups at its terminals enables: the acceleration of the cationic polymerization reaction of the epoxy resin; the acceleration of the reaction with the coumarone resin; and a reduction in stress of a resin cured product by a reaction between a ring-opened epoxy group and a hydroxy group, and is effective in improving the adhesiveness to the inorganic material layer.

The number of the terminal hydroxy groups of the polyhydric alcohol is preferably 2 (bifunctional) or 3 (trifunctional). Specifically, when the number of the terminal hydroxy groups is 2 or more, an accelerating effect on the cationic polymerization reaction of the epoxy resin is sufficiently obtained. Meanwhile, when the number of the terminal hydroxy groups is large, the photosensitive resin composition may be reduced in adhesiveness to the inorganic material layer by being brought into contact with a solvent or ink. In view of the foregoing, the number of the terminal hydroxy groups is preferably 2 or 3. Further, the polyhydric alcohol is preferably free of a perfluoroalkyl group and a perfluoroalkylene group. The presence of the perfluoroalkyl group and the perfluoroalkylene group unevenly distributes the alcohol toward an air interface after film formation, which may reduce an improving effect on the adhesiveness to the inorganic material layer. In addition, when the photosensitive resin composition is used as a dry film, the polyhydric alcohol containing a perfluoroalkyl group and a perfluoroalkylene group, the alcohol being unevenly distributed to the surface of the composition in contact with the inorganic material layer, is present in a large amount. As a result, a reduction in adhesiveness to the inorganic material layer occurs. The molecular weight of the polyhydric alcohol is preferably 3,000 or less. When the molecular weight is 3,000 or less, the reduction in improving effect on the adhesiveness due to a reduction in ratio of a hydroxy group equivalent in a molecule of the alcohol, or a reduction in resolution of the composition as a photolithography material can be suppressed. The photosensitive resin composition (2) may also contain the above-mentioned polyhydric alcohol from the viewpoint of the reactivity between the epoxy resin and the coumarone resin.

In addition, in order that the polyhydric alcohol may not disappear in a heating step before the developing step, such as prebaking or PEB, at the time of the production of a microstructure, the alcohol preferably has a boiling point higher than a temperature in the heating step to be used.

The addition amount of the polyhydric alcohol is preferably from 0.5 part by mass to 30.0 parts by mass, more preferably from 1.0 part by mass to 10.0 parts by mass with respect to 100 parts by mass of the epoxy resin in each of the photosensitive resin compositions. When the addition amount is small, an improving effect on the adhesiveness to the inorganic material layer is small. An excessively large addition amount may cause a reduction in resolution of the composition as a photolithography material. The average molecular weights (Mw and Mn) of a resin to be used in the present disclosure may be calculated by gel permeation chromatography (GPC: manufactured by, for example, Shimadzu Corporation) in terms of polystyrene.

In addition, it is required that the cured product of the photosensitive resin composition (2) serving as the ejection orifice forming member have mechanical strength, and hence the photosensitive resin composition (2) preferably contains an epoxy resin that is trifunctional or more. In addition, the epoxy equivalent is preferably less than 500 from the viewpoint of the reactivity.

Examples of commercial epoxy resins that may be used in the photosensitive resin composition (1) serving as the flow path forming member and the photosensitive resin composition (2) serving as the ejection orifice forming member include: “CELLOXIDE 2021”, “GT-300” series, “GT-400” series, and “EHPE3150” (product names, all of which are manufactured by Daicel Chemical Industries, Ltd.); “jER1031S”, “jER1004”, “jER1007”, “jER1009”, “jER1009F”, “jER1009SK”, “jER1010”, “jER1256”, and “157S70” (product names, all of which are manufactured by Mitsubishi Chemical Corporation); “EPICLON N-695”, “EPICLON N-865”, “EPICLON 4050”, “EPICLON 7050”, “EPICLON HP-6000”, “EPICLON HP-4710”, “EPICLON HP-7200” series, and “EPICLON EXA-4816” (product names, all of which are manufactured by DIC Corporation); “EPOX-MK R1710” (product name, manufactured by Printec Corporation); “DENACOL” series (product name, manufactured by Nagase ChemteX Corporation); and “EP-4000” series (product name, manufactured by ADEKA Corporation).

The photoacid generator to be added to each of the photosensitive resin compositions is preferably a photoacid generator selected from a sulfonic acid compound, a diazomethane compound, a sulfonium salt compound, an iodonium salt compound, a disulfone-based compound, and the like. Examples of commercial products thereof include: “ADEKA Optomer (trademark) SP-170”, “ADEKA Optomer (trademark) SP-172”, and “ADEKA Optomer (trademark) SP-150” (product names, all of which are manufactured by ADEKA Corporation); “BBI-103” and “BBI-102” (product names, all of which are manufactured by Midori Kagaku Co., Ltd.); “IBPF”, “IBCF”, “TS-01”, and “TS-91” (product names, all of which are manufactured by Sanwa Chemical Co., Ltd.); “CPI (trademark)-210”, “CPI (trademark)-300”, and “CPI (trademark)-410” (product names, all of which are manufactured by San-Apro Ltd.); and “Irgacure (trademark) 290” (product name, manufactured by BASF Japan). Those photoacid generators may be used as a mixture thereof.

Further, a silane coupling agent may be added for the purpose of improving the adhesive performance. A commercial silane coupling agent is, for example, “Silquest A-187 (trademark)” (product name, manufactured by Momentive Performance Materials Inc.).

In addition, a sensitizer such as an anthracene compound, a basic substance such as an amine, an acid generator that generates toluenesulfonic acid that is weakly acidic (pKa=−1.5 to 3.0), or the like may be added for improving the pattern resolution or adjusting the sensitivity of each of the photosensitive resin compositions (exposure value needed for its curing). A commercial acid generator that generates toluenesulfonic acid is “TPS-1000” (product name, manufactured by Midori Kagaku Co., Ltd.), “WPAG-367” (product name, manufactured by Wako Pure Chemical Industries, Ltd.), or the like.

In addition, for example, “SU-8” series and “KMPR (trademark) 1000” (product names, manufactured by Nippon Kayaku Co., Ltd.), and “TMMR S2000” and “TMMF S2000” (product names, manufactured by Tokyo Ohka Kogyo Co., Ltd.) commercially available as negative dry film photoresists may each be used as the photosensitive resin composition free of the coumarone resin.

### EXAMPLES

The present disclosure is described in more detail below by way of Examples. However, the present disclosure is not limited to these Examples.

A liquid ejection head was produced through steps illustrated in FIG. 3A to FIG. 3H by using each of the photosensitive resin compositions (1) and (2) of Examples and Comparative Examples shown in Table 1. In each table, composition is represented in “part(s) by mass.”

TABLE 1

| | |
|---|---|
| Product | Example |

| | Component | name | 1 | 2 | 3 | 4 | 5 | 6 | 7 |
|---|---|---|---|---|---|---|---|---|---|
| Photosensitive | Epoxy resin | N695 | 100 | 100 | 100 | 100 | 100 | 100 | 100 |
| resin | | 1009F | 200 | 200 | 200 | 200 | 200 | 200 | 200 |
| composition (1) | Coumarone resin | G-90 | 0 | 0 | 0 | 0 | 0 | 7.5 | 7.5 |
| | | V-120 | 7.5 | 15 | 30 | 45 | 75 | 0 | 7.5 |
| | | L-20 | 0 | 0 | 0 | 0 | 0 | 0 | 0 |
| | Parts of coumarone resin | | 2.5 | 5.0 | 10.0 | 15.0 | 25.0 | 2.5 | 5.0 |
| | with respect to 100 parts | | | | | | | | |
| | of epoxy resin | | | | | | | | |
| | Photoacid | 410S | 8.5 | 8.5 | 8.5 | 8.5 | 8.5 | 8.5 | 8.5 |
| | generator | SP-172 | 10 | 10 | 10 | 10 | 10 | 10 | 10 |
| | Acid generator | TPS-1000 | 2.3 | 2.3 | 2.3 | 2.3 | 2.3 | 2.3 | 2.3 |
| | Silane coupling | A-187 | 10 | 10 | 10 | 10 | 10 | 10 | 10 |
| | agent | | | | | | | | |
| | Additive | PEG600 | 7.5 | 7.5 | 7.5 | 7.5 | 7.5 | 7.5 | 7.5 |
| | Solvent | PGMEA | 650 | 650 | 650 | 650 | 650 | 650 | 650 |
| Photosensitive | Epoxy resin | 157S70 | 100 | 100 | 100 | 100 | 100 | 100 | 100 |
| resin | Coumarone resin | G-90 | 0 | 0 | 0 | 0 | 0 | 0 | 0 |
| composition (2) | | V-120 | 0 | 0 | 0 | 0 | 0 | 0 | 0 |
| | | L-20 | 0 | 0 | 0 | 0 | 0 | 0 | 0 |
| | Parts of coumarone resin | | 0.0 | 0.0 | 0.0 | 0.0 | 0.0 | 0.0 | 0.0 |
| | with respect to 100 parts | | | | | | | | |
| | of epoxy resin | | | | | | | | |
| | Epoxy resin | HP7200 | 0 | 0 | 0 | 0 | 0 | 0 | 0 |
| | having | | | | | | | | |
| | dicyclopentadiene | | | | | | | | |
| | skeleton | | | | | | | | |
| | Photoacid | 410S | 1.5 | 1.5 | 1.5 | 1.5 | 1.5 | 1.5 | 1.5 |
| | generator | | | | | | | | |
| | Acid generator | TPS-1000 | 0.03 | 0.03 | 0.03 | 0.03 | 0.03 | 0.03 | 0.03 |
| | Silane coupling | A-187 | 1 | 1 | 1 | 1 | 1 | 1 | 1 |
| | agent | | | | | | | | |
| | Solvent | PGMEA | 165 | 165 | 165 | 165 | 165 | 165 | 165 |

| | |
|---|---|
| Product | Example |

| | Component | name | 8 | 9 | 10 | 11 | 12 | 13 | 14 |
|---|---|---|---|---|---|---|---|---|---|
| Photosensitive | Epoxy resin | N695 | 100 | 100 | 100 | 100 | 100 | 100 | 100 |
| resin | | 1009F | 200 | 200 | 200 | 200 | 200 | 200 | 200 |
| composition (1) | Coumarone resin | G-90 | 0 | 0 | 0 | 0 | 0 | 0 | 0 |
| | | V-120 | 0 | 0 | 0 | 0 | 0 | 0 | 0 |
| | | L-20 | 0 | 0 | 0 | 0 | 0 | 0 | 0 |
| | Parts of coumarone resin | | 0.0 | 0.0 | 0.0 | 0.0 | 0.0 | 0.0 | 0.0 |
| | with respect to 100 parts | | | | | | | | |
| | of epoxy resin | | | | | | | | |
| | Photoacid | 410S | 8.5 | 8.5 | 8.5 | 8.5 | 8.5 | 8.5 | 8.5 |
| | generator | SP-172 | 10 | 10 | 10 | 10 | 10 | 10 | 10 |
| | Acid generator | TPS-1000 | 2.3 | 2.3 | 2.3 | 2.3 | 2.3 | 2.3 | 2.3 |
| | Silane coupling | A-187 | 10 | 10 | 10 | 10 | 10 | 10 | 10 |
| | agent | | | | | | | | |
| | Additive | PEG600 | 7.5 | 7.5 | 7.5 | 7.5 | 7.5 | 7.5 | 7.5 |
| | Solvent | PGMEA | 650 | 650 | 650 | 650 | 650 | 650 | 650 |
| Photosensitive | Epoxy resin | 157S70 | 100 | 100 | 100 | 100 | 100 | 100 | 100 |
| resin | Coumarone resin | G-90 | 0 | 0 | 0 | 0 | 0 | 5 | 2.5 |
| composition (2) | | V-120 | 1.5 | 2.5 | 5 | 10 | 25 | 0 | 2.5 |
| | | L-20 | 0 | 0 | 0 | 0 | 0 | 0 | 0 |
| | Parts of coumarone resin | | 1.5 | 2.5 | 5.0 | 10.0 | 25.0 | 5.0 | 5.0 |
| | with respect to 100 parts | | | | | | | | |
| | of epoxy resin | | | | | | | | |
| | Epoxy resin | HP7200 | 0 | 0 | 0 | 0 | 0 | 0 | 0 |
| | having | | | | | | | | |
| | dicyclopentadiene | | | | | | | | |
| | skeleton | | | | | | | | |
| | Photoacid | 410S | 1.5 | 1.5 | 1.5 | 1.5 | 1.5 | 1.5 | 1.5 |
| | generator | | | | | | | | |
| | Acid generator | TPS-1000 | 0.03 | 0.03 | 0.03 | 0.03 | 0.03 | 10.03 | 0.03 |
| | Silane coupling | A-187 | 1 | 1 | 1 | 1 | 1 | 1 | 1 |
| | agent | | | | | | | | |
| | Solvent | PGMEA | 165 | 165 | 165 | 165 | 165 | 165 | 165 |

| | | Product | Example | Comparative Example | | | | | |
|---|---|---|---|---|---|---|---|---|---|
| | Component | name | 15 | 1 | 2 | 3 | 4 | 5 | 6 |
| Photosensitive | Epoxy resin | N695 | 100 | 100 | 100 | 100 | 100 | 100 | 100 |
| resin | | 1009F | 200 | 200 | 200 | 200 | 200 | 200 | 200 |
| composition (1) | Coumarone resin | G-90 | 0 | 0 | 0 | 0 | 0 | 0 | 0 |
| | | V-120 | 7.5 | 90 | 0 | 0 | 0 | 0 | 0 |
| | | L-20 | 0 | 0 | 0 | 90 | 0 | 0 | 30 |
| | Parts of coumarone resin | | 2.5 | 30.0 | 0.0 | 30.0 | 0.0 | 0.0 | 10.0 |
| | with respect to 100 parts | | | | | | | | |
| | of epoxy resin | | | | | | | | |
| | Photoacid | 410S | 8.5 | 8.5 | 8.5 | 8.5 | 8.5 | 8.5 | 8.5 |
| | generator | SP-172 | 10 | 10 | 10 | 10 | 10 | 10 | 10 |
| | Acid generator | TPS-1000 | 2.3 | 2.3 | 2.3 | 2.3 | 2.3 | 2.3 | 2.3 |
| | Silane coupling | A-187 | 10 | 10 | 10 | 10 | 10 | 10 | 10 |
| | agent | | | | | | | | |
| | Additive | PEG600 | 7.5 | 0 | 7.5 | 7.5 | 7.5 | 7.5 | 7.5 |
| | Solvent | PGMEA | 650 | 650 | 650 | 650 | 650 | 650 | 650 |
| Photosensitive | Epoxy resin | 157S70 | 100 | 100 | 100 | 100 | 100 | 100 | 100 |
| resin | Coumarone resin | G-90 | 0 | 0 | 0 | 0 | 0 | 0 | 0 |
| composition (2) | | V-120 | 2.5 | 0 | 30 | 0 | 0 | 0 | 0 |
| | | L-20 | 0 | 0 | 0 | 0 | 30 | 0 | 30 |
| | Parts of coumarone resin | | 2.5 | 0.0 | 10.0 | 0.0 | 30.0 | 0.0 | 30.0 |
| | with respect to 100 parts | | | | | | | | |
| | of epoxy resin | | | | | | | | |
| | Epoxy resin | HP7200 | 0 | 0 | 0 | 0 | 0 | 20 | 0 |
| | having | | | | | | | | |
| | dicyclopentadiene | | | | | | | | |
| | skeleton | | | | | | | | |
| | Photoacid | 410S | 1.5 | 1.5 | 1.5 | 1.5 | 1.5 | 1.5 | 1.5 |
| | generator | | | | | | | | |
| | Acid generator | TPS-1000 | 0.03 | 10.03 | 0.03 | 0.03 | 0.03 | 0.03 | 0.03 |
| | Silane coupling | A-187 | 1 | 1 | 1 | 1 | 1 | 1 | 1 |
| | agent | | | | | | | | |
| | Solvent | PGMEA | 165 | 165 | 165 | 165 | 165 | 165 | 165 |

In the table, the product names are specifically as described below.
N695: product name “EPICLON (trademark) N695”, manufactured by DIC Corporation
1009F: product name “jER (trademark) 1009F”, manufactured by Mitsubishi Chemical Corporation
157S70: product name “jER (trademark) 157S70”, manufactured by Mitsubishi Chemical Corporation
HP7200: product name “EPICLON (trademark) HP7200”, manufactured by DIC Corporation
G-90, V-120, and L-20: product names “Nitto Resin (trademark) Coumarone” series, manufactured by Nitto Chemical Co., Ltd.
G-90: softening point: 90° C., hydroxyl value: 25, average molecular weight: 770
V-120: softening point: 120° C., hydroxyl value: 30, average molecular weight: 960
L-20: softening point: (not disclosed), hydroxyl value: 65, average molecular weight: 220
410S: manufactured by San-Apro Ltd., product name “CPI (trademark)-410S”
SP-172: product name “ADEKA Optomer (trademark) SP-172”, manufactured by ADEKA Corporation
TPS-1000: manufactured by Midori Kagaku Co., Ltd.
A-187: product name “Silquest A-187 (trademark)”, manufactured by Momentive Performance Materials, Inc.
PEG: polyethylene glycol
PGMEA: propylene glycol monomethyl ether acetate

First, as illustrated in FIG. 2A, a PET film having a thickness of 100 μm was prepared as the film base material 21. As illustrated in FIG. 2B, the photosensitive resin composition (1) having the composition shown in Table 1 was applied onto the PET film by a spin coating method, and was baked at 90° C. for 20 minutes so that its PGMEA solvent was volatilized. Thus, the first resin layer 13 having a thickness of 15.0 μm was formed as the resin layer 22 to produce a dry film.

As illustrated in FIG. 3A, the substrate 1 formed of silicon, which had, on its surface side, the energy-generating elements 2 each formed of tantalum silicon nitride (TaSiN), was prepared.

As illustrated in FIG. 3B, SiCN was formed into a film having a thickness of 0.3 μm as the inorganic material layer 4 on the surface side of the substrate 1 by a plasma CVD method so as to cover the energy-generating elements 2.

Subsequently, Ta was formed into a film having a thickness of 0.25 μm as the protective layer 5 by a sputtering method. Further, the inorganic material layer 4 and the protective layer 5 were subjected to patterning through a photolithography step and reactive ion etching.

As illustrated in FIG. 3C, the supply port 3 was formed. The supply port 3 was formed by: forming an etching mask having an opening through use of a positive photoresist formed of “OFPR” (trademark) (manufactured by Tokyo Ohka Kogyo Co., Ltd.); and performing reactive ion etching through the opening of the etching mask. The reactive ion etching was performed with an ICP etching apparatus (manufactured by Alcatel Micro Machining Systems, model number: 8E) by a Bosch process. After the formation of the supply port 3, the etching mask was removed with a peeling liquid.

As illustrated in FIG. 3D, the first resin layer 13 formed of the photosensitive resin composition (1) was formed. Specifically, the first resin layer 13 was transferred onto the substrate 1 having arranged therein the energy-generating elements 2 and the supply port 3 while the dry film including the first resin layer 13 produced above was heated at 80° C. and pressurized. After that, the PET film was peeled from the first resin layer 13 with a peeling tape (not shown).

As illustrated in FIG. 3E, the first resin layer 13 was subjected to pattern exposure with an i-line exposure stepper (manufactured by Canon Inc., product name: i5) at an exposure value of 16,000 J/m² through the flow path forming mask 14 having a flow path pattern. Heat treatment was further performed at 50° C. for 5 minutes to cure the exposed portion of the layer. Thus, the flow path forming member 6 was formed.

As illustrated in FIG. 3F, the second resin layer 15 formed of the photosensitive resin composition (2) was laminated. First, in the same manner as in the dry film including the first resin layer, the photosensitive resin composition (2) shown in Table 1 was applied onto a PET film having a thickness of 100 μm, and was baked at 90° C. for 5 minutes so that its solvent was volatilized. Thus, the second resin layer 15 having a thickness of 5.0 μm was formed to form a dry film. Next, the second resin layer 15 of the dry film was transferred and laminated onto the unexposed portion of the first resin layer 13 and the flow path forming member 6 that was the exposed portion of the layer by using a lamination method while being heated at 50° C.

Further, the liquid repellent layer 11 was formed on the second resin layer 15 formed of the photosensitive resin composition (2).

A liquid repellent containing a condensate of a hydrolyzable silane compound having a perfluoropolyether represented by the following formula (I) was used for the liquid repellent layer 11. The condensate of the hydrolyzable silane compound having a perfluoropolyether was prepared by the following procedure. 13.81 Grams (0.0496 mol) of y-glycidoxypropyltriethoxysilane, 4.42 g (0.0248 mol) of methyltriethoxysilane, 5.96 g (0.0248 mol) of phenyltrimethoxysilane, 1.05 g (0.0008 mol) of the compound represented by the following formula (I), 6.54 g of water, 19.06 g of ethanol, and 4.22 g of hydrofluoroether were loaded into a flask with a cooling pipe, and were stirred at room temperature for 5 minutes. After that, the mixture was heated to reflux for 33 hours to provide the condensate. In this case, a theoretical solid content concentration calculated on the assumption that all hydrolyzable groups of the silane compound have been subjected to hydrolysis and condensation is 26.5%. ²⁹Si-NMR was measured and the degree of condensation was calculated to be 55%. A product obtained by adding an epoxy resin, a photoacid generator, and an alcohol shown in Table 2 to a product obtained by diluting the condensate with ethanol so that the solid content concentration became 7.0% was used as the liquid repellent. The liquid repellent was applied onto the second resin layer 15 by slit coating so that its thickness after drying became 0.5 μm, and was baked at 50° C. for 5 minutes to laminate the liquid repellent layer 11.

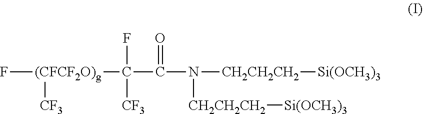

In the formula (I), “g” represents an integer of from 4 to 6.

TABLE 2

| | | Loading amount |
|---|---|---|
| Component | Product name | (part(s) by mass) |
| Condensate of hydrolyzable silane | — | 15 |
| compound having perfluoropolyether | | |
| (7 wt % ethanol solution) | | |
| Epoxy resin | EHPE3150 | 15 |
| (40 wt % ethanol solution) | | |
| Photoacid generator | 410S | 0.5 |
| (20 wt % PGMEA solution) | | |
| Solvent | PGMEA | 5 |
| | 2-Butanol | 15 |
| | Ethanol | 53 |

In the table, the product name is specifically as described below. EHPE3150: manufactured by Daicel Corporation

As illustrated in FIG. 3G, the second resin layer 15 was subjected to pattern exposure with an i-line exposure stepper (manufactured by Canon Inc., product name: i5) at an exposure value of 1,100 J/m² through the ejection orifice forming mask 16 having an ejection orifice pattern. Heat treatment was further performed at 90° C. for 5 minutes to cure the exposed portion of the resin layer. Thus, the ejection orifice forming member 10 was formed.

As illustrated in FIG. 3H, the uncured portions of the first resin layer 13, the second resin layer 15, and the liquid repellent layer 11 were collectively removed by development with PGMEA for 1 hour to form the flow path 7, the ejection orifices 8, and the nozzle portions 9, and the resultant was cured with heat at 200° C. to provide a liquid ejection head.

### Evaluation

### <Ejection Orifice Shape and Flow Path Shape>

In the liquid ejection heads produced in Examples 1 to 15 and Comparative Examples 1 to 6, the lengths and number of cracks occurring in cured products were evaluated with an optical microscope (manufactured by Nikon Corporation). The evaluation criteria are as described below.
⊚: The length of a crack occurring in part of the cured product is less than 3 μm, or no crack is observed.
∘: The length of a crack occurring in part of the cured product is 3 μm or more and less than 15 μm.
x: The length of a crack occurring in part of the cured product is 15 μm or more.
xx: The length of a crack occurring in part of the cured product is 15 μm or more and a crack is observed on the entire surface of the cured product.

### <Falling Amount>

In each of the liquid ejection heads produced in Examples 1 to 15 and Comparative Examples 1 to 6, after the lamination of the liquid repellent layer 11, a falling amount corresponding to the depth of the falling of the entirety of a resin layer in the upper portion of the supply port 3 was measured. The extent to which the upper surface of the liquid repellent layer 11, which was a uniform flat surface in a region that did not correspond to the position of the supply port 3, was depressed toward the supply port 3 at the position of the opening of the supply port 3 was adopted as the falling amount. The falling amount was determined by measuring how deep the deepest portion was from the uniform surface of the liquid repellent layer 11 with a laser microscope (Keyence Corporation). An evaluation was performed by the following criteria.
⊚: The falling amount is less than 0.5 μm.
∘: The falling amount is 0.5 μm or more and less than 1.5 μm.
x: The falling amount is 1.5 μm or more.

### <Swelling Resistance>

The liquid ejection heads produced in Examples 1 to 11 and Comparative Examples 1 to 5 were immersed in the following inks shown in Table 3, and were left to stand for 50 hours under the conditions of 121° C. and 2 atm. The thickness of the liquid ejection head before and after the immersion in the ink was measured with a white-light interference microscope (manufactured by Hitachi High-Tech Science Corporation), and the swelling resistance was evaluated with a change ratio of the thickness. The evaluation criteria are as described below.
⊚: The change ratio of the thickness before and after the immersion was 1% or less.
∘: The change ratio of the thickness before and after the immersion was more than 1% and 3% or less.
Δ: The change ratio of the thickness before and after the immersion was more than 3% and 5% or less.
x: The change ratio of the thickness before and after the immersion was more than 5% and 10% or less.

TABLE 3

| Blended component | Part(s) by mass |
|---|---|
| Diethylene glycol | 10 |
| 2-Pyrrolidone | 30 |
| 1,2-Hexanediol | 7 |
| ACETYLENOL | 1 |
| Black pigment | 3 |
| Pure water | 49 |

The evaluation results of Examples and Comparative Examples are shown in Table 4.

TABLE 4

| | Example | | | | | | | | | | | | | | |
|---|---|---|---|---|---|---|---|---|---|---|---|---|---|---|---|
| | 1 | 2 | 3 | 4 | 5 | 6 | 7 | 8 | 9 | 10 | 11 | 12 | 13 | 14 | 15 |
| Shapes of ejection | ⊚ | ⊚ | ⊚ | ⊚ | ◯ | ⊚ | ⊚ | ⊚ | ⊚ | ⊚ | ⊚ | ◯ | ⊚ | ⊚ | ⊚ |
| orifice and flow path | | | | | | | | | | | | | | | |
| Falling amount | ⊚ | ⊚ | ⊚ | ⊚ | ◯ | ◯ | ◯ | ⊚ | ⊚ | ⊚ | ⊚ | ⊚ | ⊚ | ⊚ | ⊚ |
| Swelling resistance | ◯ | ◯ | ⊚ | ⊚ | ⊚ | ◯ | ⊚ | ◯ | ◯ | ◯ | ⊚ | ⊚ | ◯ | ⊚ | ⊚ |

Comparative Example

| | 1 | 2 | 3 | 4 | 5 | 6 |
|---|---|---|---|---|---|---|
| Shapes of ejection | XX | XX | X | XX | X | XX |
| orifice and flow path | | | | | | |
| Falling amount | ◯ | ◯ | X | ◯ | ◯ | X |
| Swelling resistance | ⊚ | ⊚ | ◯ | X | ◯ | ⊚ |

As shown in Table 4, the liquid ejection heads produced in Examples each had satisfactory shapes of an ejection orifice and a flow path, and showed high swelling resistance. In particular, in each of Examples 1, 2, 3, 4, 6, 7, and 15 in which the content of the coumarone resin in the photosensitive resin composition (1) serving as a flow path forming member was less than 30 parts by mass with respect to 100 parts by mass of the epoxy resin, a satisfactory flow path shape was obtained. In addition, in each of Examples 8, 9, 10, 11, 13, 14, and 15, in which the content of the coumarone resin in the photosensitive resin composition (2) serving as an ejection orifice forming member was less than 30 parts by mass with respect to 100 parts by mass of the epoxy resin, a satisfactory ejection orifice shape was obtained. In addition, in each of Examples 1, 2, 3, 4, 8, 9, 10, 11, 13, 14, and 15, a coumarone resin having a high softening point (product name: V-120) was used, and the content was set to fall within a specified range. Accordingly, the softening points of the photosensitive resin composition (1) serving as the flow path forming member and the photosensitive resin composition (2) serving as the ejection orifice forming member were not reduced, and the falling amounts thereof were particularly small. With regard to the swelling resistance, the liquid ejection heads of Examples 3 to 5, 7, 11, 12, 14, and 15 each having a high content of the coumarone resin were particularly satisfactory.

Meanwhile, in each of the liquid ejection heads produced in Comparative Examples 1, 2, 3, 5, and 6, even when the liquid ejection head had swelling resistance, a crack occurred or a falling was observed. In Comparative Example 4, the coumarone resin was dissolved at the time of the application of the liquid repellent, and the swelling resistance was reduced. In Comparative Example 6, the photosensitive resin composition (1) had a content of the coumarone resin falling within a specified range, but the content of the coumarone resin in the photosensitive resin composition (2) was large, and hence the softening point was reduced. As a result, not only a crack occurred but a pattern shape was also broken.

### <Printing Evaluation>

Each of the liquid ejection heads produced in Examples and Comparative Examples was filled with an ink formed of ethylene glycol, urea, isopropyl alcohol, N-methylpyrrolidone, a black dye, and water at a ratio of 5/3/2/5/3/82. The ink ejection head was used to perform an ejection evaluation, and the print quality was evaluated by measuring impingement accuracy. The evaluation was performed based on the following criteria. The term “impingement accuracy” means a positioning shift (the distance from a desired impingement position to the center of an ink droplet) of the ink droplet impinged on paper. The evaluation results of the print quality were collectively shown in Table 5. The evaluation criteria were as described below.
∘: Satisfactory (the impingement accuracy is 2 μm or less)
x: Deteriorated (the impingement accuracy is 5 μm or more)

TABLE 5

| | | | | | | | | | | | | | | | | Comparative | | | | | |
|---|---|---|---|---|---|---|---|---|---|---|---|---|---|---|---|---|---|---|---|---|---|
| | Examples | | | | | | | | | | | | | | | Examples | | | | | |
| | 1 | 2 | 3 | 4 | 5 | 6 | 7 | 8 | 9 | 10 | 11 | 12 | 13 | 14 | 15 | 1 | 2 | 3 | 4 | 5 | 6 |
| Print | ◯ | ◯ | ◯ | ◯ | ◯ | ◯ | ◯ | ◯ | ◯ | ◯ | ◯ | ◯ | ◯ | ◯ | ◯ | X | X | X | X | X | X |
| quality | | | | | | | | | | | | | | | | | | | | | |

In each of the liquid ejection heads produced in Examples, the print quality was satisfactory. Meanwhile, in each of the liquid ejection heads produced in Comparative Examples, the print quality deteriorated owing to a crack occurring in the ejection orifice or the flow path as compared to each of the liquid ejection heads produced in Examples.

As described above, according to the present disclosure, the method of producing a liquid ejection head having swelling resistance and a stable shape can be provided.

According to one embodiment of the present disclosure, the method of producing a microstructure in which both of swelling resistance and shape stability are achieved can be provided. In addition, according to one embodiment of the present disclosure, the liquid ejection head can be provided as a microstructure.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2023-038669, filed Mar. 13, 2023, which is hereby incorporated by reference herein in its entirety.

What is claimed is:

1. A method of producing a microstructure comprising:
forming a first resin layer formed of a photosensitive resin composition (1) on a substrate, followed by pattern exposure; and
laminating a second resin layer formed of a photosensitive resin composition (2) on the first resin layer having been subjected to the pattern exposure, followed by pattern exposure,
wherein the photosensitive resin composition (1) and the photosensitive resin composition (2) each contain an epoxy resin and a photoacid generator,
wherein at least one of the photosensitive resin composition (1) or the photosensitive resin composition (2) further contains a coumarone resin, and wherein a content of the coumarone resin is less than 30 parts by mass with respect to 100 parts by mass of a content of each of the epoxy resin of the photosensitive resin composition (1) and the epoxy resin of the photosensitive resin composition (2).

2. The method of producing a microstructure according to claim 1, wherein the coumarone resin has a weight-average molecular weight of from 500 to 1,000.

3. The method of producing a microstructure according to claim 1, wherein the coumarone resin has a hydroxyl value of 40 or less.

4. The method of producing a microstructure according to claim 1, wherein the coumarone resin has a softening point of 90° C. or more.

5. The method of producing a microstructure according to claim 1, wherein the coumarone resin is insoluble in an alcohol solvent.

6. The method of producing a microstructure according to claim 1, wherein the photosensitive resin composition (1) and the photosensitive resin composition (2) are each a negative cationically polymerizable resin composition.

7. The method of producing a microstructure according to claim 1, wherein the epoxy resins are each an epoxy resin that is bifunctional or more.

8. The method of producing a microstructure according to claim 7, wherein the epoxy resin of the photosensitive resin composition (1) includes a bifunctional epoxy resin and an epoxy resin that is trifunctional or more.

9. The method of producing a microstructure according to claim 7, wherein the epoxy resin of the photosensitive resin composition (2) is an epoxy resin that is trifunctional or more.

10. The method of producing a microstructure according to claim 1, wherein at least one of the photosensitive resin composition (1) or the photosensitive resin composition (2) further contains a polyhydric alcohol.

11. The method of producing a microstructure according to claim 1, wherein at least one of the first resin layer or the second resin layer is formed by a method using a dry film.

12. The method of producing a microstructure according to claim 11, wherein the method using a dry film is a method including transferring the dry film while heating the dry film.

13. The method of producing a microstructure according to claim 1, further comprising forming a liquid repellent layer on the second resin layer.

14. The method of producing a microstructure according to claim 13, wherein the liquid repellent layer contains a fluorine compound.

15. The method of producing a microstructure according to claim 1, wherein each of the first resin layer and the second resin layer is exposed with exposure light including light having the same wavelength, and an exposure value of the second resin layer is smaller than that of the first resin layer.

16. The method of producing a microstructure according to claim 1, wherein the microstructure is a liquid ejection head including a liquid supply port on the substrate,
wherein the first resin layer forms a flow path forming member for forming a flow path that communicates to the liquid supply port, and
wherein the second resin layer forms an ejection orifice forming member for forming: a nozzle portion that communicates to the flow path; and an ejection orifice that
communicates to the nozzle portion, the ejection orifice being configured to eject a liquid.

17. A liquid ejection head comprising:
a substrate; and
a flow path forming member and an ejection orifice forming member arranged on the substrate,
wherein the flow path forming member and the ejection orifice forming member are formed of cured products of a photosensitive resin composition (1) and a photosensitive resin composition (2) each containing an epoxy resin and a photoacid generator, respectively,
wherein at least one of the photosensitive resin composition (1) or the photosensitive resin composition (2) further contains a coumarone resin, and
wherein a content of the coumarone resin is less than 30 parts by mass with respect to 100 parts by mass of a content of each of the epoxy resin of the photosensitive resin composition (1) and the epoxy resin of the photosensitive resin composition (2).
